(19) United States
(12) Patent Application Publication
(10) Pub. No.: US 2003/0213772 A9
(43) Pub. Date: Nov. 20, 2003

(54) Integrated semiconductor substrate bevel cleaning apparatus and method

(76) Inventors: Yeuk-Fai Edwin Mok, San Francisco, CA (US); Alexander Ko, Sunnyvale, CA (US); Bernardo Donoso, San Jose, CA (US); Joseph J. Stevens, San Jose, CA (US)

Correspondence Address: APPLIED MATERIALS, INC., 2881 SCOTT BLVD. M/S 2061, SANTA CLARA, CA, 95050, US

(21) Appl. No.: 09/785,815

(22) Filed: Feb. 16, 2001

Related U.S. Application Data
(63) Continuation-in-part of application No. 09/350,210, filed on Jul. 9, 1999, now Pat. No. 6,267,853.
(63) Continuation-in-part of application No. 09/350,212, filed on Jul. 9, 1999, now Pat. No. 6,516,815.
(63) Continuation-in-part of application No. 09/614,406, filed on Jul. 12, 2000, now Pat. No. 6,494,219.
(60) Provisional application No. 60/237,908, filed on Oct. 4, 2000.

(51) Int. Cl. C25F 3/30; C23F 1/00; H01L 21/302; H01L 21/461

(52) U.S. Cl. 216/92; 216/100; 216/105; 134/1.3; 438/748; 438/754

(57) ABSTRACT

An integrated semiconductor substrate bevel cleaning system that enables transfer of substrates through the bevel cleaner either with or without substrate processing within the bevel cleaner. The invention provides an integrated bevel cleaning apparatus comprising a transfer position, a rinsing position and an etching position.

This application claims benefit of U.S. provisional patent application No. 60/237,908, filed Oct. 4, 2000, hereby incorporated by reference in its entirety.

### BACKGROUND OF THE DISCLOSURE

1. Field of the Invention

The present invention relates to an integrated apparatus and method for performing bevel cleaning on semiconductor substrates.

2. Description of the Background

Sub-quarter micron, multi-level metallization is one of the key technologies for the next generation of ultra large scale integration (ULSI). The multilevel interconnects that lie at the heart of this technology require planarization of interconnect features formed in high aspect ratio apertures, including contacts, vias, lines and other features. Reliable formation of these interconnect features is very important to the success of ULSI and to the continued effort to increase circuit density and quality on individual substrates.

As circuit densities increase, the widths of vias, contacts and other features, as well as the dielectric materials between them, decrease to less than 250 nanometers, whereas the thickness of the dielectric layers remains substantially constant, with the result that the aspect ratios for the features (i.e., their height divided by width), increases. Many traditional deposition processes such as physical vapor deposition (PVD) and chemical vapor deposition (CVD), do not effectively fill structures in which the aspect ratio exceeds 4:1, and particularly where the aspect ratio exceeds 10:1. Therefore, much effort is presently being directed toward the formation of void-free, nanometer-sized features having high aspect ratios such as 4:1 or higher. Additionally, as the feature widths decrease, the device current remains constant or increases, which results in an increased current density in the feature.

Elemental aluminum (Al) and its alloys have been the traditional metals used to form lines and plugs in semiconductor processing because of aluminum's perceived low electrical resistivity, its superior adhesion to silicon dioxide (SiO₂), its ease of patterning, and the ability to obtain it in a highly pure form. However, aluminum has a higher electrical resistivity than other more conductive metals such as copper, and aluminum also can suffer from electromigration leading to the formation of voids in the conductor.

Copper and its alloys have lower resistivities than aluminum and significantly higher electromigration resistance as compared to aluminum. These characteristics are important for supporting the higher current densities experienced at high levels of integration and increase device speed. Copper also has good thermal conductivity and is available in a highly pure state. Therefore, copper is becoming a choice metal for filling sub-quarter micron, high aspect ratio interconnect features on semiconductor substrates.

Despite the desirability of using copper for semiconductor device fabrication, choices of fabrication methods for depositing copper into very high aspect ratio features, such as a 4:1, having 0.35μ (or less) wide vias are limited. As a result of these process limitations, electroplating, which had previously been limited to the fabrication of lines on circuit boards, is presently being used to fill vias and contacts on semiconductor devices.

Metal electroplating is generally known and can be achieved by a variety of techniques. A typical method generally comprises physical vapor depositing a barrier layer over the feature surfaces, physical vapor depositing a conductive metal seed layer, preferably copper, over the barrier layer, and then electroplating a conductive metal over the seed layer to fill the structure/feature. Finally, the deposited layers and the dielectric layers are planarized, such as by chemical mechanical polishing (CMP), to define a conductive interconnect feature.

For efficient substrate processing, layers, such as copper layers, electroplated onto a substrate must be smooth and regular (i.e., planar, uniform or flat) before other processing steps are performed. Irregularities (i.e., bumps) present on the electroplated layer surface hinder substrate processing efficiency by causing problems such as peeling and/or flaking and resulting in reduced yield.

One particular problem encountered in current electroplating processes is that the area of an electroplated layer about (i.e., at or near) the edge of the layer typically contains irregularities. These irregularities often occur due to excess electroplated material being deposited about the edge of the layer, and thus in the region of the substrate about the edge or perimeter of the substrate (this region of the substrate is known as the bevel of the substrate). In this regard, it has been observed that, during an electroplating process, an area of the layer near the edge of the substrate receives a higher current density than the remaining area of the layer, resulting in a higher rate of deposition of electroplated material near the edge of the substrate. The excess material accumulates to form the bevel of the substrate and is sometimes called the “edge bead”. Additionally, contact points present at or near the edge of the layer may break after electroplating, causing layer irregularities about the edge of the substrate. Furthermore, the metallization near the edge of the substrate tends to “peel off” the substrate.

A multiple step bevel cleaning process (i.e. a “bevel cleaner”) may be used to remove the bevel. A bevel cleaning process involves applying an etchant to the bevel region to remove the metal near the substrate edge, i.e., the metallization is removed from the substrate at a certain distance from the substrate edge. The etchant is then removed from the substrate through rinsing with deionized water and lastly the substrate is dried by spinning the substrate. Each of these tasks is performed in a different machine. The use of many machines between which a substrate must be transported increases the risk of substrate damage and contamination. Additionally, the movement of substrates requires a substantial amount of time that impacts throughput for the substrate processing system.

Therefore, a need exists in the art for an integrated bevel cleaner that enables transfer of substrates through the bevel cleaner either with or without edge bead removal and substrate cleaning.

### SUMMARY OF THE INVENTION

The present invention provides an integrated semiconductor substrate bevel cleaning system that enables transfer of substrates through the bevel cleaner either with or without substrate processing within the bevel cleaner. The invention provides an integrated bevel cleaning apparatus comprising a transfer position, a rinsing position and an etching position. The invention also provides a method for etching electroplated material from a substrate within an integrated bevel cleaning apparatus, comprising introducing the substrate into a transfer position within the integrated bevel cleaning apparatus, raising the substrate into a rinse position within the integrated bevel cleaning apparatus where a rinsing process is performed, and raising the substrate into an etching position within the integrated bevel cleaning apparatus where an etchant is applied to the edge bead. Once the edge bead has been etched for a predefined period of time, the substrate is then lowered into the rinse position and rinsed, then the substrate is returned to the transfer position for removal from the apparatus. The transfer position is accessible from both sides of the apparatus such that a substrate transfer robot on one side of the apparatus can be loading a substrate, while a substrate transfer robot on the other side of the apparatus can be removing a substrate.

### BRIEF DESCRIPTION OF THE DRAWINGS

The teachings of the present invention can be readily understood by considering the following detailed description in conjunction with the accompanying drawings, in which:

FIG. 1 depicts a schematic, cross-sectional view of an integrated bevel cleaner of the invention;

FIG. 2a depicts a schematic, cross-sectional view of the integrated bevel cleaner of FIG. 1, with a substrate positioned at the transfer position;

FIG. 2b depicts a schematic, cross-sectional view of the integrated bevel cleaner of FIG. 1, with a substrate positioned at the rinse position;

FIG. 2c depicts a cross-sectional view of the integrated bevel cleaner of FIG. 1 with a substrate positioned at the etch position;

FIG. 3 depicts a perspective view of the etchant dispensing apparatus of the integrated bevel cleaner of FIG. 1, showing the nozzles of the etchant dispense arms dispensing etchant onto a substrate;

FIG. 4 depicts a flow diagram of a process sequence for the integrated bevel cleaning apparatus;

FIG. 5 depicts a schematic, top view of the integrated bevel cleaner of FIG. 1;

FIG. 6 depicts a cluster tool including the integrated bevel cleaner of FIG. 1; and

FIG. 7 is a perspective view of an alternative rinsing arm having a plurality of nozzles.

To facilitate understanding, identical reference numerals have been used, where possible, to designate identical elements that are common to the figures.

### DETAILED DESCRIPTION

The present invention provides an integrated semiconductor substrate bevel cleaner (IBC) that enables transfer of substrates through the bevel cleaner either with or without substrate bevel cleaning within the bevel cleaner. Specifically, the invention provides a bevel cleaner that uses a substrate positioning assembly to move the substrate into a transfer position where the substrate is moved into and out of the cleaner, a substrate rinsing position and a substrate etching position. With this bevel cleaner, an edge bead on a substrate edge can be removed and the substrate rinsed and spun dry within a single apparatus. The transfer position can be used to pass substrates through the IBC without processing. In this manner, the IBC can be used as a component in a larger cluster tool such that substrates can be passed from an electroplating cell, be processed in the IBC, passed to other processing stages, then passed back through the IBC and out of the cluster tool.

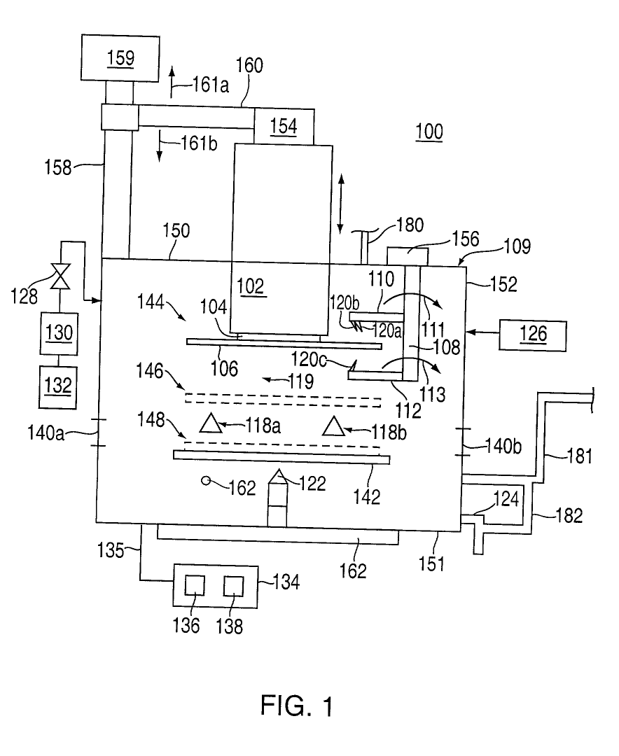

FIG. 1 depicts a schematic, cross-sectional view of one embodiment of an integrated bevel cleaning apparatus, or integrated bevel cleaner (IBC) 100 of the invention. The IBC comprises a lid assembly 150, walls 152 and a bottom 151. The lid assembly 150 may be coupled to the walls 152 of the IBC 100 via a hinge or other coupling mechanism so that the lid assembly can be lifted to permit access to the interior of the IBC 100 for cleaning and/or servicing of the IBC 100.

Processes and process sequences within the IBC 100 are preferably controlled by a system controller 134, such as a programmable computer having one or more central processing units (CPUs) 136 and support circuitry containing memory 138 (a computer readable medium) for storing associated control software. The system controller 134 enables automated control of the various processes and process sequences occurring within the IBC 100 via bi-directional communication with various components of the IBC 100 through a signal carrier such as signal cables 135.

A drain 124 is disposed in the bottom 151 to allow draining of fluids from the IBC 100. In one embodiment, the drain 124 has a vented exhaust system to enable constant flow through the drain 124 as fluids are used to process a substrate. The IBC 100 may also have an exhaust duct 181 proximate the bottom 151 of the IBC 100. The exhaust duct 181 may have a drain 182 connected to the chamber drain 124 for draining fluids from the exhaust duct 124. To prevent fluids from being drawn into the exhaust duct, the exhaust duct rises above the level of the bottom 151. Filtered air is supplied through a port 180 in the top of the IBC 100. The air exits the IBC 100 through the exhaust duct 181.

The walls 152 comprise one or more openings such as slit valves 140a,b to provide access to the interior of the IBC 100 by a substrate handler, such as a robot (not shown), that moves substrates into and out of the IBC 100. To facilitate high throughput of the IBC 100, the IBC 100 may comprise two slit valves 140a and 140b. As such, one slit valve may be used to load a substrate into the IBC 100 while the other slit valve is used to remove a substrate from the IBC 100.

A spindle assembly 102 is disposed within the IBC 100 to move a substrate 106 vertically within the IBC 100 and to rotate, or spin the substrate 106. A substrate gripper, such as a vacuum chuck 104, as is well-known in the art, is disposed on the spindle assembly 102 for gripping the substrate 106. As depicted in FIG. 1, the substrate 106 is “vacuum-chucked” to the vacuum chuck 104.

A spindle assembly linkage 160 is attached to the spindle assembly 102 by a fastener or fasteners such as screws (not shown). The spindle assembly linkage 160 is coupled to a spindle lift 158. The spindle lift 158 comprises an actuator 159 for vertically moving the spindle assembly linkage 160 as shown be arrows 161a,b. The spindle lift actuator 159 may be any form of mechanism that can vertically move the spindle assembly 102 such as a lead screw and stepper motor, ball screw and stepper motor, hydraulic system, rack and pinion assembly and the like.

A spindle assembly motor assembly 154 is coupled to the spindle assembly linkage 160 for causing rotational motion of the vacuum chuck 104 and the substrate 106. As such, the spindle assembly 102 spins the substrate 106. The motor 154 spins the substrate at between 200 and more than 1000 rpm. Generally, 700 rpm or more is sufficient during the etching process to produce a sharp vertical profile at the edge of the metallization layer.

The interior of the IBC 100 comprises a transfer area, or transfer position 148, a rinse area, or rinse position 146 and an etch area, or etch position 144. The spindle assembly 102 is used to move the substrate 106 vertically between the process position. In FIG. 1, the substrate 106 is shown positioned at the etch position 144, shown in phantom positioned at the rinse position 146 and shown in phantom positioned at the transfer position 148.

In the embodiment depicted in FIG. 1, the transfer position 148 is under the rinse position 146, the rinse position 148 is under the etch position 144, and the substrate 106 is moved therebetween by the spindle assembly 102 while the substrate 106 is in a face-down position (i.e., with the processing side or front side of the substrate 106 in a face-down position). However, the invention also contemplates embodiments in which the vertical positioning of the stations is opposite that depicted in FIG. 1, and embodiments wherein a substrate is moved and/or processed in a face-up position. For this reason, it is to be understood that terms such as “up”, “down”, “face-up”, “face-down”, “over”, “under” and the like are not intended to limit the invention to the specifically described configuration, but rather are intended only to indicate relative position.

The transfer position 148 comprises a substrate centering hoop 142. The hoop 142 is an annular member with an inwardly sloping inner wall such that the substrate, when released by a substrate handler (not shown) places the substrate 106 in a centrally located position. The substrate handler uses a substrate holder such as an edge gripper or a vacuum chuck. The substrate is transported in a face-down orientation and enters the IBC 100 via one of the slit valves 140a,b. The gripper or chuck releases the substrate into the hoop 142. Placement of the substrate 106 in the substrate centering hoop 142 ensures that the substrate 106 is properly aligned to be secured by vacuum suction, or vacuum chucked to the vacuum chuck 104 of the spindle assembly 102.

Alternatively, the substrate centering hoop 142 may be substituted with some other form of substrate self centering apparatus such as a plurality of fingers that grip the edge of the substrate. Each of the fingers has a tapered tip to urge the substrate into alignment. Six to twelve fingers may be used for centering a substrate. These fingers may be used to actively maintain the substrate at a central location in the IBC 100.

In one embodiment, an infra-red substrate sensor 162 is disposed in the transfer station 148 under the substrate centering hoop 142 to provide the system controller 134 with substrate position information useful in controlling processing and process sequencing.

A hoop rinse nozzle 122 is disposed at the bottom 151 of the IBC 100 for dispensing a rinsing fluid such as deionized water to rinse the substrate centering hoop 142. The rinsing fluid ensures that chemicals do not become deposited upon the hoop 142.

One or more lower substrate rinse nozzles (two are shown as nozzles 118a,b) and one upper substrate rinse nozzle 119 are positioned to dispense a rinsing fluid such as deionized water to rinse the substrate 106 while the substrate 106 is positioned at the rinse position 146. The lower rinse nozzles 118a,b are adapted to dispense rinsing fluid upward to the face-down front side of the substrate 106. The upper rinse nozzle 119 is adapted to dispense rinsing fluid to the face-up backside of the substrate 106 while the substrate 106 is in the rinse position.

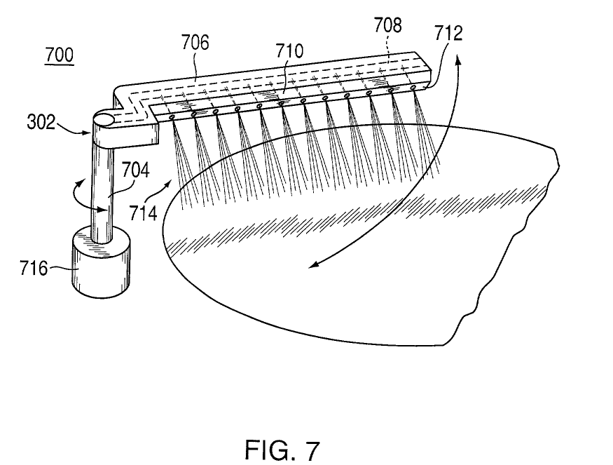

The nozzles 118a,b and/or 119 can be attached to the chamber wall, bottom of the chamber, upon the spindle assembly 102, or mounted on a dispensing arm. FIG. 7 depicts a dispensing arm assembly 700 that can be used to dispense rinsing fluid. The dispensing arm 702 comprises a stalk 704 and a manifold 706. The stalk 704 is hollow and carries fluid to the manifold 706. The manifold 706 has a central distribution conduit 708 and a plurality of generally linearly arranged dispensing apertures 710. The apertures 710 are small holes extending from the outer surface 712 of the manifold into the conduit 708 such that rinsing fluid in the conduit 708 is distributed to each of the apertures 710. In this manner, the rinsing fluid 714 is spayed from the array of apertures 710 onto the substrate. The stalk 704 dispensing arm assembly 700 is coupled to an actuator 716, such as a stepper motor, that rotates the arm 702 into and out of a rinsing position. The actuator 716 can be activated to move the arm 702 in a dynamic manner while rinsing the substrate. As such, various locations on the substrate can be rinsed more than other locations, e.g., the substrate center region can be supplied with more rinsing fluid than the edge regions. In lieu of a specific actuator 716 for the arm 702, the dispensing arm 702 can be driven by the same actuator that is used to move the etchant dispensing arm assembly 109. As such, as the etchant dispensing arm assembly 109 is moved into and out of position, the rinsing fluid dispensing arm assembly 700 is moved out of and in to position, i.e, the two arms move in an inverse relationship.

Rinsing fluid such as deionized water is provided to the IBC 100 by a rinse fluid supply 126 that is located external to the IBC 100 and fluidly connected to the IBC 100. Rinse fluid such as deionized water is delivered to the hoop rinse nozzle 122 and the substrate rinse nozzles 118a-b, 119 by valving (not shown). In the embodiment shown, the rinsing fluid is provided to the IBC 100 without being heated. However, in other embodiments of the invention, the rinsing fluid may first be heated before being provided to the IBC 100.

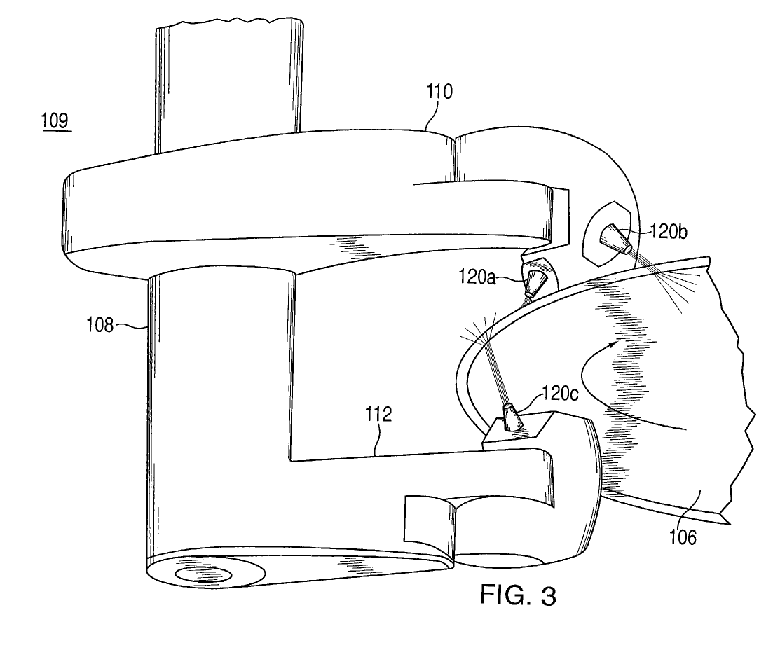

FIG. 3 depicts a perspective view of one embodiment of the etchant dispensing arm assembly 109 of the IBC 100. For best understanding of the etchant dispensing arm assembly 109, the reader should simultaneously review FIGS. 1 and 3 while reading the following description. An etchant dispense arm linkage 108 is disposed within the IBC 100, and attached thereto are an upper dispense arm 110 and a lower dispense arm 112. Two upper etchant dispense nozzles 120a,b are disposed at a distal end of the upper etchant dispense arm 110, and a lower etchant dispense nozzle 120c is disposed at a distal end of the lower dispense arm 112. The nozzles deliver etchant to the bevel of the substrate 106 positioned at the etch position 144 while the spindle assembly 102 spins the substrate 106 at 200 to more than 1000 rpm. The etchant removes metallization from 1 to 5 mm from the edge of the substrate (i.e., an edge exclusion). Various widths of edge exclusion can be achieved by positioning the dispense arm at different angles relative to the substrate surface.

Etchant, such as a solution of sulfuric acid, hydrogen peroxide and deionized water, is provided to the IBC 100 by an etchant supply 132 located external to the IBC 100 and fluidly connected to the IBC 100. The etchant may be heated by an etchant heater 130 before being directed to the upper and lower etchant dispense nozzles 120a-c. The sulfuric acid solution is generally heated to about 50° C. Other etchants that are well-known for removal of metallization, such as nitric acid solutions, may also be used. A pressure regulator valve 126 controls the flow of etchant to the IBC 100. An etchant dispense arm linkage motor 156, such as a stepper motor, is coupled to the etchant dispense arm linkage 108 for rotating the etchant dispense arm linkage 108 and the upper and lower etchant dispense arms 110, 112 as shown by arrows 111 and 113. The rotation of the dispense arms 110 and 120 enables the arms to clear the substrate 106 so that the substrate 106 may be lowered into the rinse position 146 after etching is complete.

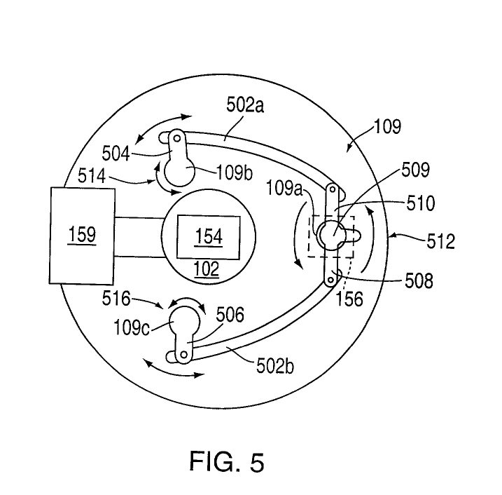

To facilitate rapid etching of the edge bead, the IBC 102 comprises three dispense arm assemblies that are all rotatably driven by a single stepper motor 156. FIG. 5 depicts a schematic, top view of the IBC 100 and the dispense arm assembly 109. The assembly 109 comprises the motor 156, a first actuator element 512, a pair of control linkage arms 502A and 502B, second actuator element 514 and third actuator element 516. The first actuator element 512 is coupled to the dispense arm assembly 109A, the second actuator element 514 is coupled to the dispense arm assembly 109B, and the third actuator element 516 is coupled to the dispense arm assembly 109C. The first actuator element 512 is coupled to the stepper motor 156. The first actuator element 512 comprises a pair of master control arms 508 and 510 that extend from a central hub 509. When the central hub 509 is rotated the arms 508 and 510 move. Each arm 508 and 510 is coupled to a linkage arm 502A and 502B that is, in turn, coupled to an control horns 504 and 506 of the second and third actuator elements 514 and 516. When the hub 509 rotates from a single motor 156, all three actuator elements 512, 514 and 516 rotate to position the dispenser nozzles proximate the substrate edge. Of course, more than one motor could be used to rotate the dispenser assemblies 109A, 109B, and 109C in to and out of position.

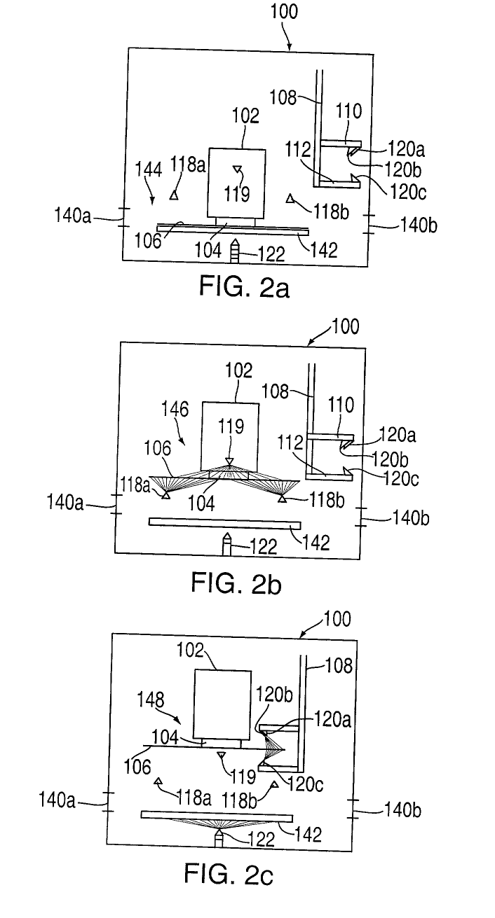

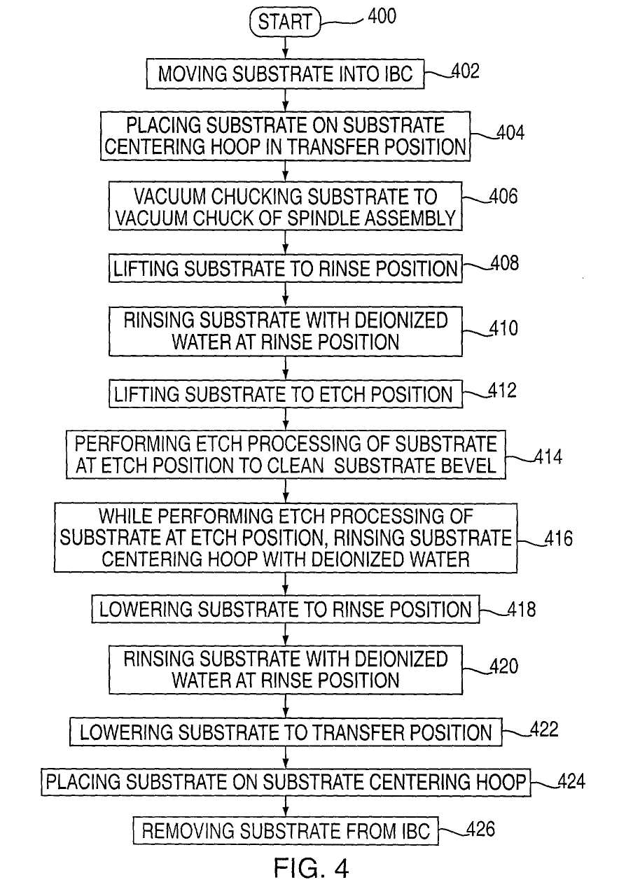

One embodiment of the invention is shown and described in detail with reference to FIGS. 2a-2c and FIG. 4. FIGS. 2a-2c schematically depict the IBC 100 in various operating positions and FIG. 4 depict a flow diagram representing the steps of operation of the IBC 100. The best understanding of the invention will be realized when simultaneously viewing FIGS. 2a-2c and FIG. 4 while reading the following description. This process is generally controlled by the computer controller 134 of FIG. 1 by executing a control program stored in memory 138.

The process begins at step 400 and proceeds to step 402. At step 402, a substrate handler, such as a robot (not shown), delivers the substrate 106, after substrate processing such as copper electroplating processing, into the IBC 100 via one of the slit valves 140a-b and, at step 404, places the substrate 106 face-down into the substrate centering hoop 142 at the transfer position 148. Once the substrate is positioned and the substrate handler exits the IBC 100, the slit valve is closed. At step 406, the spindle assembly 102 is lowered so that the vacuum chuck 104 contacts the back of the substrate 106, as depicted in FIG. 2a, and vacuum suction is applied to vacuum chuck the substrate 106 to the vacuum chuck 104.

At step 408, the substrate 106 is then lifted to the rinse position 146, and, at step 410, deionized water is dispensed by the lower and upper substrate rinse nozzles 118a-b, 119 for about 15 seconds to rinse the substrate 106, including rinsing off electrolyte solution on the substrate 106, as depicted in FIG. 2b. In other embodiments of the invention, a different number of rinse nozzles and different rinse durations may be utilized to rinse the substrate 106.

After rinse processing of the substrate 106, the spindle assembly 102 lifts (at step 412) the substrate 106 to the etch position 148. While the upper and lower etchant dispense arms 110, 112 are in a non-processing position, as depicted in FIGS. 2a-b, the substrate can be placed in the etch position 148. At step 414, the etchant dispense arm(s) are moved into position and the etchant is sprayed onto the exclusion area of the substrate to remove the edge bead. The width of the exclusion area is determined by the angle of the dispense arms 110 and 112 and nozzles 120a,b, and c with respect to the substrate 106. While etchant is sprayed the spindle assembly 102 spins the substrate at between 200 and 1000 rpm.

While the etchant is applied, at step 416 and as shown in FIG. 2c, a rinsing solution (e.g., deionized water) is applied to the substrate centering hoop 142 to remove any contaminates from the hoop such that the substrate will not be contaminated when placed back upon the hoop 142. Once the etching process is complete, the dispense arm(s) 108 are rotated away from the substrate 106 and, at step 418, the substrate is lowered to the rinsing position 146. While the substrate is spinning, the rinse solution (deionized water) is applied at step 420 from three nozzles 118a, b and c to the substrate 106 to remove the etchant and metal residue form the substrate. The rinse position 146 of the IBC 100 is shown in FIG. 2b. While in the rinse position, the rinsing solution may be stopped and the substrate spun at high rpm until the substrate is dry.

Once rinsed, the substrate spinning is stopped and, at step 422, the substrate is lowered into the transfer position. At step 424, the substrate is positioned in the substrate centering hoop 142. At step 426, one of the slit valves 140a,b opens and the substrate handler enters the IBC 100 and removes the substrate 106. The process of substrate edge bead removal and cleaning is now complete.

Although the depicted embodiment shows the transfer position 144 at the bottom, the rinse position 146 in the middle and the etch position 148 at the top, those skilled in the art will realize that the positions do not have to be in those specific locations. As such, any arrangement of positions is deemed within the scope of this invention.

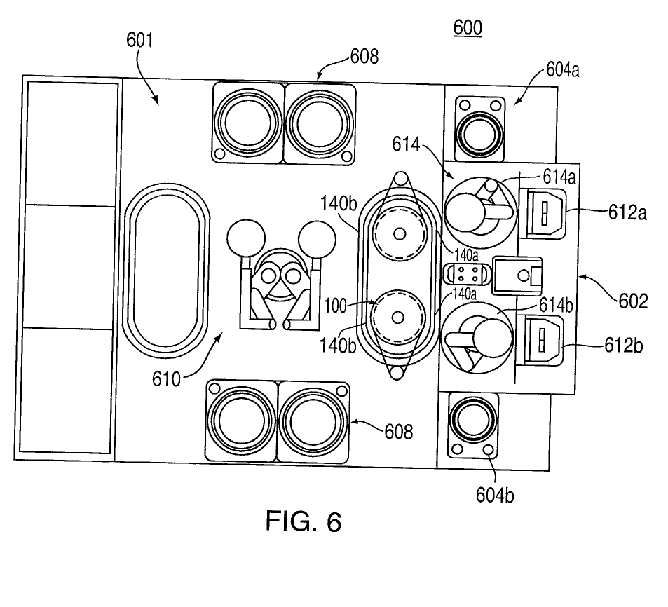

FIG. 6 depicts a schematic, top view of the IBC 100 in a cluster tool 600 comprising a processing region 601 and a load station 602. The load station 602 comprises at least one load lock 612A, 612B, a plurality of processing or metrology chambers (such as anneal chambers 604A, 604B) and a substrate handler 614 (robots 614A, 614B). The processing region 601 comprises a second substrate handler 610, at least one electroplating chamber 608 (two are shown) and the IBC 100. The IBC 100 forms a connective link between the two regions 601 and 602. The substrates are accessed from the load locks by the first substrate handler 614 and processed by a chamber 604 or placed through slit valve 140a into the transfer position of the IBC 100. From the transfer position, the second substrate handler 610 can access the substrate through slit valve 140b. The second substrate handler 610 then places the substrate into an electroplating cell or chamber 608. While awaiting the electroplating process to complete, the foregoing substrate positioning process can be repeated to position another substrate in another electroplating cell. In the illustrative system, two substrates (a substrate pair) can be moved and processed at the same time.

When a substrate is fully plated, the substrate is removed from the cell 608 by the substrate handler 610 and placed in the transfer position of the IBC 100. The IBC 100 removes the edge bead and cleans the substrate as discussed above. Once the substrate is positioned in the transfer position, the first substrate handler 614 enters the IBC 100 and retrieves the substrate. The substrate may now be processed or analyzed in the chambers 604 or placed in one of the load locks 612A or 612B.

Although various embodiments which incorporate the teachings of the present invention have been shown and described in detail herein, those skilled in the art can readily devise many other varied embodiments that still incorporate these teachings.

What is claimed is:

1. An integrated bevel cleaning (IBC) apparatus, comprising:
a transfer position where a substrate is positioned for processing and where a substrate is positioned after processing;
a rinse position where the substrate is rinsed; and
an etch position where the substrate edge bead is removed; and
an actuator for positioning the substrate in the transfer position, the rinse position and the etch position.

2. The IBC apparatus of claim 1 further comprising a substrate centering hoop for supporting the substrate in the transfer position.

3. The IBC apparatus of claim 2 further comprising a substrate centering hoop rinsing nozzle.

4. The IBC of claim 1 further comprising at least one rinsing nozzle located proximate said rinsing position for rinsing at least an edge region of the substrate.

5. The IBC of claim 4 wherein said at least one rinsing nozzle is a plurality of nozzles positioned to rinse both sides of the substrate.

6. The IBC of claim 1 wherein said transfer position is accessible by at least one slit valve.

7. The IBC apparatus of claim 1 wherein said actuator comprises a spindle assembly for retaining a substrate and rotating the substrate, and a linear actuator for raising and lowering said spindle assembly.

8. The IBC apparatus of claim 7 wherein said spindle assembly comprises a vacuum chuck.

9. The IBC of claim 1 further comprising at least one etchant dispenser arm positioned proximate the etch position to apply etchant to the substrate.

10. The IBC apparatus of claim 9 wherein said etchant is applied to an edge exclusion zone of said substrate.

11. The IBC apparatus of claim 9 wherein said at least one etchant dispenser arm is rotatable into a position near the substrate and away form the substrate.

12. The IBC apparatus of claim 11 wherein said at least one etchant dispenser arm is at least three etchant dispenser arms.

13. The IBC apparatus of claim 12 wherein said at least three etchant dispenser arms are coupled to a single motor for simultaneously rotating the at least three dispenser arms.

14. A method for etching electroplated material from a substrate within an integrated bevel cleaning (IBC) apparatus, comprising:
introducing the substrate into a transfer position within the IBC apparatus;
moving the substrate to a rinse position within the IBC apparatus;
rinsing the substrate in the rinse position within the IBC apparatus;
moving the substrate to an etch position within the IBC apparatus; and
etching material from the substrate in the etch position within the IBC apparatus.

15. The method of claim 14 wherein the substrate is rotated while in the rinse position and the etch position.

16. The method of claim 14 wherein the introducing step further comprises opening at least one of a plurality of slit valves.

17. The method of claim 14 wherein the step of etching comprises positioning at least one etchant dispenser arm proximate the substrate.

18. The method of claim 17 wherein the at least one etchant dispenser arm comprises three etchant dispenser arms that are coupled to a single motor that imparts rotation in all three etchant dispenser arm simultaneously.

19. A system for processing substrates comprising:
a loading station having at least one first chamber;
a process region having at least one second chamber;
an integrated bevel cleaning (IBC) apparatus comprising a transfer position through which a substrate can be passed from said load station to said process region without processing being performed in said IBC apparatus.

20. The system of claim 19 wherein said at least one second chamber is an electroplating chamber.

21. The system of claim 19 wherein said load station comprises a first substrate handler and said second process region comprises a second substrate handler.

22. The system of claim 19 wherein said IBC apparatus performs edge bead removal and substrate cleaning.
